(19) United States
(12) Patent Application Publication
(10) Pub. No.: US 2026/0282476 A1
(43) Pub. Date: Sep. 17, 2026

(54) LDMOS WITH ELEVATED DRIFT REGION AND METHOD OF MANUFACTURING

(71) Applicant: GlobalFoundries Singapore Pte. Ltd., Singapore (SG)

(72) Inventors: Yong Wah SEE, Singapore (SG); Guowei ZHANG, Singapore (SG); Ee Jan KHOR, Singapore (SG)

(21) Appl. No.: 19/076,477

(22) Filed: Mar. 11, 2025

(51) Int. Cl. H10D 62/17; H10D 30/01; H10D 30/65; H10D 64/00

(52) U.S. Cl. CPC H10D 62/393; H10D 30/0281; H10D 30/65; H10D 64/111

(57) ABSTRACT

A lateral current double-diffused metal oxide semiconductor (LDMOS) device includes a body region, a source region within the body region, a drain region, a drift region between the body region and the drain region, the drift region comprising a raised portion on a drain side of the drift region, a gate comprising a gate dielectric and a gate electrode, the gate dielectric comprising a first portion over the body region and a second portion over the drift region, the second portion of the gate dielectric having a thickness that is greater than a thickness of the first portion of the gate dielectric, and a field plate over the raised portion of the drift region, wherein a top surface of the raised portion of the drift region is raised above a top surface of a portion of the drift region under the gate.

### BACKGROUND

Lateral current double-diffused metal oxide semiconductor (LDMOS) transistors have been widely employed in high voltage applications. One factor which affects the performance of the LDMOS transistors is the drain-to-source on-resistance (R_{DS(on)}). Power consumption and switching speeds of an LDMOS transistor can be improved by reducing R_{DS(on)}. One technique for reducing R_{DS(on)} is to reduce the length of the drift region, which has the effect of reducing the resistance of the drift region. However, the length of the drift region controls the breakdown voltage of an LDMOS transistor, so reducing its length has the side-effect of changing voltage characteristics of the transistor. Another technique is to increase doping levels of the drift region which has the same effect of reducing the breakdown voltage. Therefore, it is desirable to provide an LDMOS transistor with a reduced R_{DS(on)} while maintaining a high breakdown voltage.

### SUMMARY

Embodiments of the present application relate to an LDMOS device, an integrated circuit, and a method for forming an LDMOS device.

In an embodiment, an LDMOS device includes a body region, a source region within the body region, a drain region, a drift region between the body region and the drain region, the drift region comprising a raised portion on a drain side of the drift region, a gate comprising a gate dielectric and a gate electrode, the gate dielectric comprising a first portion over the body region and a second portion over the drift region, the second portion of the gate dielectric having a thickness that is greater than a thickness of the first portion of the gate dielectric, and a field plate over the raised portion of the drift region. A top surface of the raised portion of the drift region is raised above a top surface of a portion of the drift region under the gate.

In an embodiment, an integrated circuit includes a semiconductor substrate, a doped body in the semiconductor substrate and doped with a first type of impurities, a source region in the semiconductor substrate and doped with the first type of impurities, a drain region in the semiconductor substrate and doped with the first type of impurities, a drift region between the body region and the drain region, the drift region comprising a raised portion on a drain side of the drift region, a gate comprising a gate dielectric and a gate electrode, the gate dielectric comprising a first portion over the body region and a second portion over the drift region, the second portion of the gate dielectric having a thickness that is greater than a thickness of the first portion of the gate dielectric, and a field plate over the raised portion of the drift region. A top surface of the raised portion of the drift region is raised above a top surface of a portion of the drift region under the gate.

In an embodiment, a method for forming an LDMOS device includes forming a doped body in a semiconductor substrate and doped with a first type of impurities, forming a source region in the semiconductor substrate and doped with the first type of impurities, forming a drain region in the semiconductor substrate and doped with the first type of impurities, forming a drift region between the body region and the drain region, the drift region comprising a raised portion on a drain side of the drift region, forming a gate comprising a gate dielectric and a gate electrode, the gate dielectric comprising a first portion over the body region and a second portion over the drift region, the second portion of the gate dielectric having a thickness that is greater than a thickness of the first portion of the gate dielectric, and forming a field plate over the raised portion of the drift region. A top surface of the raised portion of the drift region is raised above a top surface of a portion of the drift region under the gate.

### BRIEF DESCRIPTION OF THE DRAWINGS

FIG. 1 illustrates an embodiment of an LDMOS device.

FIGS. 2A to 2H illustrate an embodiment of a method of forming the LDMOS device of FIG. 1.

FIG. 3 illustrates an embodiment of an LDMOS device in which a gate and a field plate are a continuous structure.

FIG. 4 illustrates an embodiment of an LDMOS device comprising a raised portion with a curved surface.

### DETAILED DESCRIPTION

A detailed description of embodiments is provided below along with accompanying figures. The scope of this disclosure is limited by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. The figures are not drawn to scale, and features are enlarged or diminished for visual clarity.

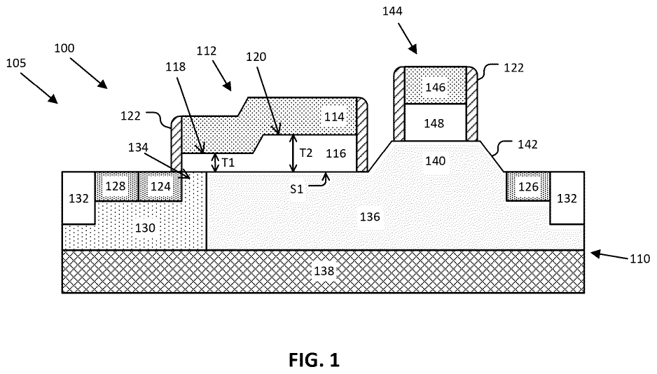

FIG. 1 illustrates an embodiment of a Lateral current double-diffused metal oxide semiconductor (LDMOS) device 100. The LDMOS device 100 may be a transistor device, and more specifically, a high voltage (HV) transistor device. The LDMOS device 100 may be employed as a switching voltage regulator for power management applications. The LDMOS device may be incorporated into an integrated circuit 105 and may be used for a consumer or industrial electrical product. The IC 105 may include other electronic devices such as memory, transistors, diodes, capacitors, etc. as known in the art.

The LDMOS device 100 may be located on a portion of a semiconductor substrate 110. The semiconductor substrate 110 may be a silicon substrate. In other embodiments, the substrate 110 may be another type of semiconductor substrate such as a silicon germanium, germanium, gallium arsenide, or silicon-on-insulator (SOI) substrate.

A gate 112 comprising a gate electrode 114 and gate dielectric 116 is located over the semiconductor substrate 110. The gate electrode 114 may comprise a polysilicon material which is doped with a first type of dopants, and the gate dielectric may comprise an oxide material such as silicon oxide. The first type of dopants may be either p-type dopants for a p-type transistor or n-type dopants for an n-type transistor. The gate dielectric 116, for example, may be a HV gate dielectric having a thickness of about 50-500 Å while the gate electrode 114 may be about 500-5000 Å thick. These values are only examples, and the specific thicknesses of the gate dielectric 116 and gate electrode 114 may be selected to suit a particular application.

In the embodiment of FIG. 1, the gate dielectric comprises a first portion 118 and a second portion 120. The first portion 118 has a first thickness T1, and the second portion 120 has a second thickness T2 that is greater than the first thickness T1. The second thickness T2 may be, for example, from 25% to 200% or greater than the first thickness T1. Accordingly, when the first thickness T1 is 100 Å, the second thickness T2 may be from 125 to 300 Å, for example. The first thickness T1 may be from about 50 to 400 Å, and the second thickness T2 may be from about 70 to 500 Å, for example. Other thicknesses are possible.

The different thicknesses may be provided to modulate electrical characteristics of a channel region 134 and drift region 136 under the gate 112 to provide a desired voltage drop between the drain and the source while reducing drain-to-source on-resistance (R_{DS(on)}) of the LDMOS device 100. The first portion 118 of the gate 112 may be on a source side of the gate over the channel region of the transistor, and the second portion 120 of the gate 112 may be on the drain side of the gate over the drift region 136 of the transistor.

The gate 112 may comprise spacers 122 over sidewalls of the gate electrode 114 and gate dielectric 116. The spacers 122 may comprise a dielectric material such as a nitride or oxide material. For example, spacers 122 may comprise one or both of a silicon oxide and a silicon nitride material. The spacers 122 may comprise multiple structures such as the sidewall spacers shown in the figure as well as L-shaped spacers (not shown). Other variations are possible.

Doped regions of the semiconductor substrate 110 include a source region 124 and a drain region 126. A top surface of the source region 124 may be coplanar with a top surface of the drain region 126. The source and drain regions 124 and 126 may be doped with the same type of dopants as the gate electrode 114, e.g. the first type of dopants. The source and drain regions 124 and 126 may each have a dopant concentration of about 1E15-1E17/cm², for example.

A doped region 128 of the semiconductor substrate may be adjacent to the source region 124 and may be doped with a second type of dopants. The second type of dopants have opposite polarity to the first type of dopants. For example, when the first type of dopants are p-type, the second type of dopants are n-type, and vice versa. The doped region 128 may have a similar dopant concentration to the source region 124 and may be a well tap or pickup for the transistor. The transistor may be isolated from adjacent structures by isolation structures such as shallow trench isolation (STI) structures 132 as shown in FIG. 1, or other isolation structures such as deep trench isolation (DTI) structures.

The source region 124 and doped region 128 may be in a doped well or body well 130 which is doped with the first type of dopants. An upper portion of the body well 130 adjacent to the gate dielectric 116 may provide a channel region 134 of the transistor. The doped well 130 may have a dopant concentration of about 1E12-1E14/cm², for example.

Drift region 136 extends laterally between the body well 130 and the drain region 126 under the gate 112. The drift region 136 connects the drain region 126 to the channel region 134 under the gate 112. The drift region 136 may have a length and dopant concentration which provide a desired R_{dson} resistance and drive current.

The drift region 136 may be doped with the same type of dopants as the gate electrode 114, e.g. the first type of dopants. For example, the drift well includes n-type dopants for a n-type transistor or p-type dopants for a p-type transistor. The dopant concentration of the drift region 134 may be less than that of the source region 124 and drain region 126. For example, the dopant concentration of the drift region 136 may be about 1E12-1E13/cm². The depth of the drift region 136 may be, for example, about 0.5-5 μm from the top substrate surface S1.

Deep well 138 underlies the body well 130 and drift region 136. The deep well 138 may be a portion of the substrate 110 which is doped with the same type of dopants as the gate electrode 114, e.g. the first type of dopants. The deep well may have a dopant concentration that is similar to and lower than the dopant concentration of the drift region 136. For example, the dopant concentration of the deep well 138 may be about 1E11-1E13/cm².

The drift region 136 includes a raised portion 140. The raised portion 140 may comprise a portion of the substrate 110 which is raised above a surface (S1) of the drift region which is located under the gate electrode 116. In some embodiments, the surface S1 of the substrate 110 including top surfaces of one or more of the source region 124, drain region 126, doped region 128 and isolation structures 132 is located at a first level, and the raised portion 140 is raised to a second level above the first level.

In some embodiments, an uppermost surface of the raised portion 140, e.g. a top surface, may be raised from about 500-2000 Å above the top surface S1 of an adjacent portion of the drift region 136, e.g. the portion of the drift region 136 which is under the gate 112 in the embodiment of FIG. 1, and the top surface of drain region 126. The width of the raised portion 140, and in particular the width of the base of the raised portion 140 may be from about0.2-1 μm, for example. The doping profile (type and concentration) of the raised portion 140 may be substantially the same as remaining portions of the drift region 136.

A field plate 144 comprising a field plate electrode 146, a field plate dielectric 148, and spacers 122 may be disposed over the raised portion 140. The field plate electrode 146 may be the same material, e.g. doped polysilicon, as the gate electrode 114, and the field plate dielectric 148 may be the same material, e.g. an oxide material, as gate dielectric 116. The field plate 144 in the embodiment of FIG. 1 is separated from the gate 112 by a space.

The field plate dielectric 148 may have a thickness that is substantially the same as the second thickness T2 of the gate dielectric 116. The length of the field plate 144 along the channel length direction may be, for example, about 0.1-3 μm, and the thickness of the field dielectric (T2) 148 may be about 200-5000 Å. The length of the gate 114 may be similar to or greater than the length of the field plate 144. For example, the gate 114 may have a length of about 0.1-5 μm. In an embodiment in which the length of the field plate 144 is longer than the length of the gate 112, the length of the gate 112 may be from 25% to 200%, or from 25% to 100% greater than the length of the field plate 144, for example.

The inventors of the present disclosure have discovered that an LDMOS device 100 comprising a drift region 136 with a raised portion 140 and a field plate 144 located on the raised portion 140 has the benefit of reducing the R_{DS(on)} compared to a conventional LDMOS layout with the same voltage drop. These improvements may be realized even when the raised portion 140 is continuous with underlying portions of the drift region 136, such that improvements may be realized with minimal processing steps when fabricating a device.

The raised portion 140 of the drift region 136 may comprise transition regions 142 between the top surface of the raised portion 140 and adjacent surface S1. In the embodiment of FIG. 1, the transition regions 142 are substantially flat sides of the raised portion 140 and the top surface of raised portion 140 is flat, but embodiments are not limited to this configuration. For example, the corners may be rounded, and in other embodiments, the raised portion 140 may have a curved surface as will be described in more detail below.

In some embodiments, the transition region 142 has an angle of from about 30 to 60 degrees with respect to the adjacent top surface S1 of the substrate 110. In an embodiment in which the raised portion 140 has a curved surface, an angle of the curved surface, e.g. an angle of a line tangential the curved surface at the base of the raised portion 140, may also be about 30 to 60 degrees with respect to the adjacent top surface S1 of the substrate 110. Embodiments in which a raised portion 140 is raised above an adjacent drain region 126 and comprises a transition region 142 between a top surface of the drain region 126 and the top surface of raised portion 140 may be effective to cause current to flow through the raised portion 140, and may have reduced edge effects compared to an embodiment that lacks a transition region.

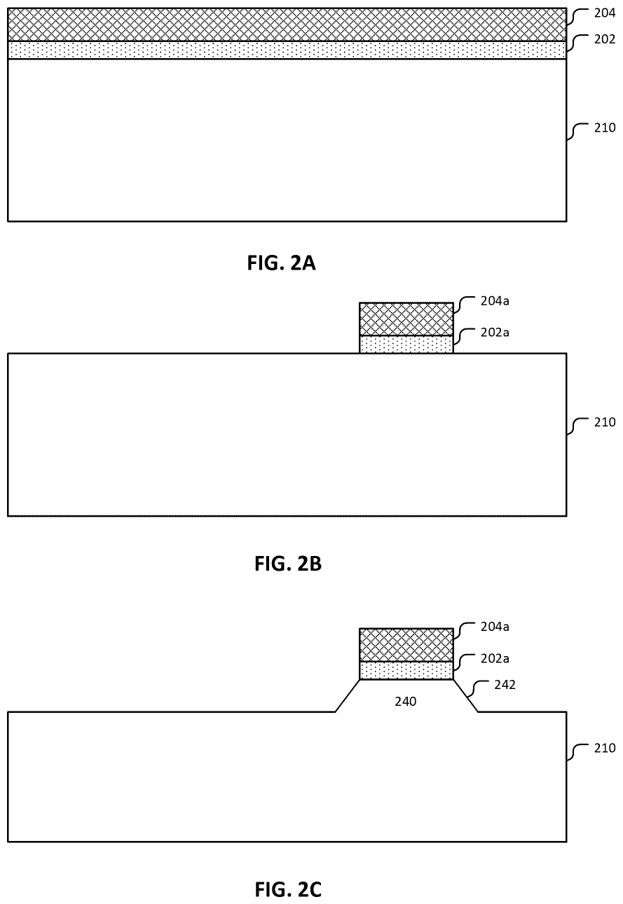

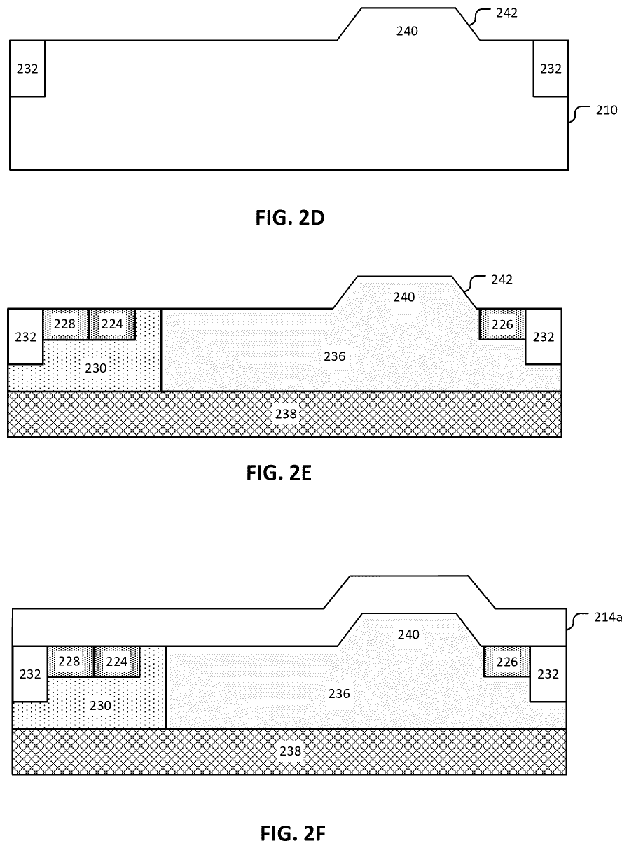

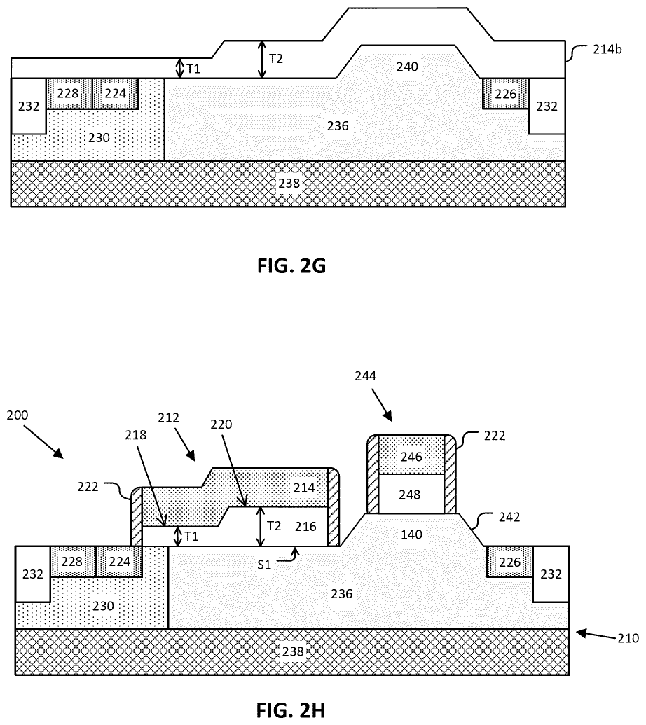

FIGS. 2A to 2H illustrate an embodiment of a process for forming an LDMOS device 200. The LDMOS device 200 may have the same structure as the LDMOS device 100 in FIG. 1. In some embodiments, a raised portion is created using a LOCal Oxidation of Silicon (LOCOS) process, elements of which are described below.

In FIG. 2A, an oxide layer 202 (e.g. silicon oxide) or pad oxide is deposited over a semiconductor substrate 210. The material at the surface of substrate 210 may be silicon. A hard mask layer 204 (e.g. silicon nitride) is then deposited over the surface of the oxide layer 202. A patterned photoresist mask (not shown) is deposited over the hard mask layer 204 and used as an etch mask to etch the hard mask layer 204 and oxide layer 202 to form the patterned oxide layer 202a and patterned hard mask layer 204a shown in FIG. 2B.

An etching process is then performed using patterned oxide layer 202a and patterned hard mask layer 204a as an etch mask to create the structure of FIG. 2C. The etching process may be controlled so that transition regions 242 have an angle of from about 30 to 60 degrees. Techniques for controlling variables of an etching process to provide a desired slope are known in the art and therefore are not explained here in detail. In other embodiments, different etch mask materials may be used in place of the hard mask and oxide materials.

In some embodiments, a LOCOS process including thermal oxidation may be used to form a substrate 410 comprising a raised portion 440 with a curved surface as seen in the embodiment of FIG. 4 as known in the art. Accordingly, in various embodiments, elements of a LOCOS process and/or other processing techniques may be used to form a substrate comprising a raised portion with transition regions 242 with an angle of from about 30 to 60 degrees.

After forming the raised portion 240, STI structures 232 are formed in the substrate 210. The STI structures 232 may be formed, for example, using a damascene process in which a planarization step uses etch chemistry that selectively removes an oxide of the STI structures 232 without removing the raised portion 240. The resulting structure is shown in FIG. 2D.

A series of implantation processes are performed to form deep well 238, drift region 236, body well 230, source region 224, drain region 226, and doped region 228 as seen in FIG. 2E. Following implantation, a gate dielectric layer 214a may be deposited over the structure of FIG. 2E to form the structure of FIG. 2F. A photoresist mask (not shown) may be patterned over the gate dielectric layer 214a and used as an etch mask to remove a portion of gate dielectric layer 214a, resulting in a layer 214b comprising two different thicknesses, T1 and T2, as seen in FIG. 2G. Next, a layer of polysilicon (not shown) may be deposited over the etched gate dielectric layer 214b. The polysilicon may be in-situ doped polysilicon that is doped with the first type of dopants. The polysilicon and dielectric layers are then etched to form the gate dielectric 216, gate electrode 214, field plate dielectric 248 and field plate electrode 246 as seen in FIG. 2H. Additional processes may be used to form spacers 222 and silicide layers over the electrodes as known in the art.

A dielectric layer (not shown) may then be formed on the substrate covering the transistor and the field plate. The dielectric layer serves as an interconnect dielectric layer in which interconnects are formed to couple to the various contact regions or terminals of the transistor and field structure. The dielectric layer may be a silicon oxide layer, for example. The dielectric layer may include upper and lower portions. The upper portion serves as an intra-metal dielectric (IMD) layer in which conductive lines are formed. The lower portion serves as an interlevel dielectric (ILD) layer in which contact plugs are formed. In one embodiment, the ILD layer is a pre-metal dielectric (PMD) layer in which contact plugs are formed to contact regions on the substrate, such as the contact regions of the transistor, including the source, drain, gate and field plate.

The upper and lower portions of the dielectric layer are separate portions. The conductive lines and contact plugs formed in the upper and lower portions may be formed using separate processes, such as single damascene processes. For example, via openings may be formed in the PMD layer using, for example, mask and etch processes such as RIE. The via opening may be filled with a conductive material and excess conductive material is removed by, for example, chemical mechanical planarization (CMP) to form a planar top surface with exposed contact plugs in the via openings.

Thereafter, the IMD layer is formed over the PMD layer. Trenches are formed in the IMD layer using mask and etch processes. The trenches correspond to conductive or metal lines and are in communication with contact plugs in the PMD layer. The trenches are filled with conductive material and excess conductive material is removed by, for example, CMP, to provide a planar top surface with exposed conductive lines. Other suitable techniques may also be employed to form the contact plugs and conductive lines. For example, RIE technique may be used or a combination of RIE and damascene technique may also be useful. For the case where the contact plugs and conductive lines are formed using separate processes, the conductive material of the plugs and lines may be different. For example, the contact plugs may be tungsten (W) plugs while the conductive lines may be copper lines.

Contact plugs (not shown) may be formed in the PMD layer and coupled to the source, drain, well tap, gate and field plate. The contact plugs coupled to the body well tap and field plate may be commonly coupled to a conductive or metal line Mx in upper portion of the dielectric layer. The body well tap and the field plate, for example, may be interconnected to a low potential or voltage source which is lower than the voltage values provided to the drain.

Additional processes may be performed to complete an IC 105. Such processes may include forming additional interlevel dielectric (ILD) layers, contact plugs, interconnect metal levels, final passivation, dicing, packaging and testing.

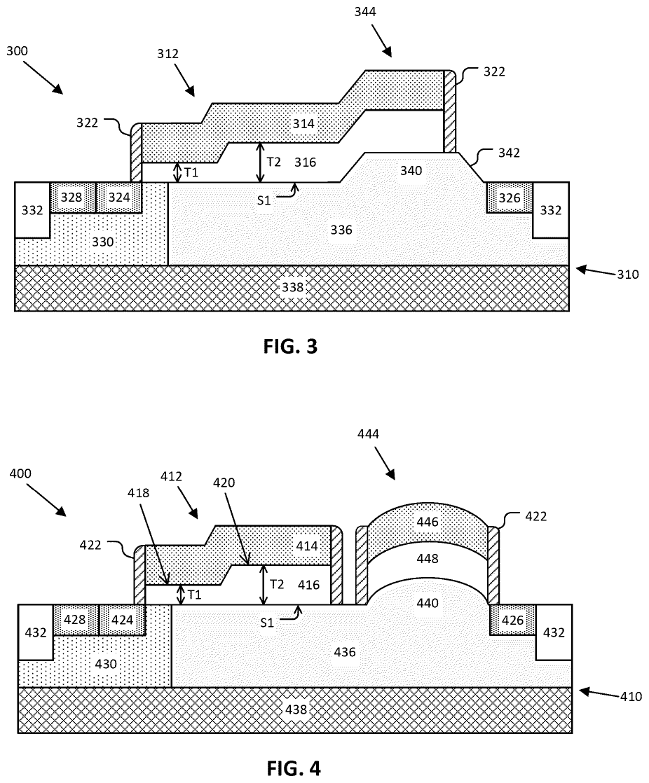

FIG. 3 illustrates another embodiment of an LDMOS device 300. The LDMOS device 300 may comprise the same or similar materials as the LDMOS device 100 described above, except that the gate 312 and the field plate 344 are a continuous structure. In the embodiment of FIG. 3, the field plate 344 portion of the continuous structure is located over the raised portion 340 of the substrate 310 and serves to distribute the electric field across the substrate between the drain region 326 and the gate 312. In this embodiment, a single contact may be used to bias the continuous structure of the gate 312 and the field plate 344.

FIG. 4 illustrates another embodiment of an LDMOS device 400. The primary difference between the LDMOS device 400 and the LDMOS device 100 is that the raised portion 440 comprises a curved upper surface. The entire upper surface of the raised portion 440 may be curved as shown in FIG. 4. In an embodiment in which the raised portion 440 has a curved surface, an angle of the curved surface, e.g. an angle of a line tangential the curved surface, may also be about 30 to 60 degrees with respect to the adjacent top surface S1 of the substrate 410 at the base of the raised portion. In addition, the electrode 446 and dielectric 448 of the field plate 444 are curved to conform to the underlying curved surface of raised portion 440. The LDMOS device of FIG. 4 may be formed using a LOCOS process, for example.

The scope of the present disclosure is not limited to the embodiments described above. For example, in another embodiment, an LDMOS device with a raised portion comprising a curved surface, as shown in FIG. 4, may also comprise a gate and field plate which are a continuous structure. Persons of skill in the art will recognize that these and other embodiments are possible within the scope of the present disclosure.

Aspects of the present disclosure have been described in conjunction with the specific embodiments thereof that are proposed as examples. Numerous alternatives, modifications, and variations to the embodiments as set forth herein may be made without departing from the scope of the claims set forth below. Accordingly, embodiments as set forth herein are intended to be illustrative and not limiting.

1. A lateral current double-diffused metal oxide semiconductor (LDMOS) device comprising:
a body region doped with a first type of impurities;
a source region within the body region and doped with the first type of impurities;
a drain region doped with the first type of impurities;
a drift region between the body region and the drain region, the drift region comprising a raised portion on a drain side of the drift region;
a gate comprising a gate dielectric and a gate electrode, the gate dielectric comprising a first portion over the body region and a second portion over the drift region, the second portion of the gate dielectric having a thickness that is greater than a thickness of the first portion of the gate dielectric; and
a field plate over the raised portion of the drift region,
wherein a top surface of the raised portion of the drift region is raised above a top surface of a portion of the drift region under the gate.

2. The LDMOS device of claim 1, wherein the raised portion of the drift region comprises a first slope facing the gate and a second slope facing the drain region.

3. The LDMOS device of claim 2, wherein the first slope and the second slope each have a respective angle of from 30 to 60 degrees.

4. The LDMOS device of claim 1, wherein the field plate comprises a dielectric layer and an electrode over the dielectric layer.

5. The LDMOS device of claim 4, wherein a thickness of the dielectric layer of the field plate is the same as a thickness of the second portion of the gate dielectric.

6. The LDMOS device of claim 4, wherein the dielectric layer of the field plate is a continuous structure with the gate dielectric and the electrode of the field plate is a continuous structure with the gate electrode.

7. The LDMOS device of claim 1, wherein the field plate is separated from the gate by a space.

8. The LDMOS device of claim 1, wherein a top surface of the source region is coplanar with a top surface of the drain region.

9. The LDMOS device of claim 1, wherein the top surface of the raised portion is curved.

10. The LDMOS device of claim 9, wherein the entire top surface of the raised portion is curved, and an angle of a line tangential to the curved surface is from 30 to 60 degrees at a base of the curve.

11. An integrated circuit comprising:
a semiconductor substrate;
a doped body in the semiconductor substrate and doped with a first type of impurities;
a source region in the semiconductor substrate and doped with the first type of impurities;
a drain region in the semiconductor substrate and doped with the first type of impurities;
a drift region between the body region and the drain region, the drift region comprising a raised portion on a drain side of the drift region;
a gate comprising a gate dielectric and a gate electrode, the gate dielectric comprising a first portion over the body region and a second portion over the drift region, the second portion of the gate dielectric having a thickness that is greater than a thickness of the first portion of the gate dielectric; and
a field plate over the raised portion of the drift region,
wherein a top surface of the raised portion of the drift region is raised above a top surface of a portion of the drift region under the gate.

12. The integrated circuit of claim 1, wherein the raised portion of the drift region comprises a first slope facing the gate and a second slope facing the drain region.

13. The integrated circuit of claim 2, wherein the first slope and the second slope each have a respective angle of from 30 to 60 degrees.

14. The integrated circuit of claim 1, wherein the field plate comprises a dielectric layer and an electrode over the dielectric layer.

15. The integrated circuit of claim 4, wherein a thickness of the dielectric layer of the field plate is the same as a thickness of the second portion of the gate dielectric.

16. The integrated circuit of claim 4, wherein the dielectric layer of the field plate is a continuous structure with the gate dielectric and the electrode of the field plate is a continuous structure with the gate electrode.

17. The integrated circuit of claim 1, wherein a top surface of the source region is coplanar with a top surface of the drain region.

18. The integrated circuit of claim 1, wherein the top surface of the raised portion is curved.

19. The integrated circuit of claim 9, wherein the entire top surface of the raised portion is curved, and an angle of a line tangential to the curved surface is from 30 to 60 degrees at a base of the curve.

20. A method of forming a semiconductor device, the method comprising:
forming a doped body in a semiconductor substrate and doped with a first type of impurities;
forming a source region in the semiconductor substrate and doped with the first type of impurities;
forming a drain region in the semiconductor substrate and doped with the first type of impurities;
forming a drift region between the body region and the drain region, the drift region comprising a raised portion on a drain side of the drift region;
forming a gate comprising a gate dielectric and a gate electrode, the gate dielectric comprising a first portion over the body region and a second portion over the drift region, the second portion of the gate dielectric having a thickness that is greater than a thickness of the first portion of the gate dielectric; and
forming a field plate over the raised portion of the drift region,
wherein a top surface of the raised portion of the drift region is raised above a top surface of a portion of the drift region under the gate.
